(19) United States
(12) Patent Application Publication
(10) Pub. No.: US 2007/0009761 A1
(43) Pub. Date: Jan. 11, 2007

(54) Hole transport material for organic electroluminescence devices and organic electroluminescence device using the same

(75) Inventors: Aki Goto, Osaka (JP); Jian Li, Osaka (JP); Taiji Tomita, Osaka (JP); Takeshi Sano, Osaka (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/363,192

(22) Filed: Feb. 28, 2006

(30) Foreign Application Priority Data
Feb. 28, 2005 (JP) 2005-054149

(51) Int. Cl. C08G 61/12; H01L 51/54; H05B 33/14

(52) U.S. Cl. 428/690; 428/917; 313/504; 257/40; 257/E51.036; 528/380; 528/377; 528/422; 528/423; 528/394; 528/397

(57) ABSTRACT

A hole transport material for organic electroluminescence devices, characterized by consisting of a copolymer having a first unit consisting of a heterocyclic compound containing a sulfur atom and a second unit consisting of a secondary or tertiary amine compound, wherein the above-mentioned hole transport material preferably further includes a third unit having a conjugated structure, preferably uses a thiophene derivative as the heterocyclic compound of the first unit, preferably uses a diphenylamine derivative and a triphenylamine derivative as the secondary or tertiary amine compound of the second unit, and includes a structure of a fluorene derivative or a structure of a phenylene derivative as the third unit, and an organic electroluminescence device using the same.

The priority Japanese Patent Application Number 2005-54149 upon which this patent application is based is hereby incorporated by reference.

### BACKGROUND OF THE INVENTION

1. Field of the Invention

The present invention relates to a hole transport material for organic electroluminescence devices and an organic electroluminescence device using the same.

2. Description of the Related Art

In recent years, as information equipment is diversified, needs for flat display devices, of which the power consumption is lower than that of CRT (cathode ray tube) commonly used, have sharply increased. As one of the flat display devices, organic electroluminescence devices (organic EL devices) which have features such as high efficiency, a low-profile, a light weight and low viewing angle dependence receive attention.

Particularly in a driving voltage, while an inorganic EL device, the same EL device, needs a high voltage of several dozen V or higher, an organic EL device can attain high emission luminance of from 100 to 100000 cd/cm² or more at a low voltage of about 10 V. Therefore, its application to full color displays and light-emitting devices for illumination is expected.

However, when its commercialization is intended, it is necessary to realize further reduction in a driving voltage of a device.

A basic structure of the organic EL device is a structure having an emission layer between a hole injection electrode and an electron injection electrode and emits light in the emission layer by hole-electron recombination. In order to enhance the injection efficiency of carriers such as a hole or an electron into the emission layer, there may be cases where a carrier injection layer, a carrier transport layer and the like are provided between the respective electrodes and the emission layer.

In order to realize the reduction in a driving voltage of a device, it is necessary to improve the mobility of a carrier or to enhance the efficiency of carrier injection into the emission layer.

As one approach for this, there is proposed a device, in which an anode is subjected to oxidation treatment to enlarge its work function and thereby injection efficiency of the hole is enhanced, in Japanese Unexamined Patent Publication No. 2001-319777.

Further, there is proposed a device, in which a substance obtained by adding an electron accepting compound to a hole transporting polymer is employed as a material of a hole injection layer, in Japanese Unexamined Patent Publication No. 2003-217862.

Further, in the conventional organic EL devices, copper phthalocyanine (CuPc), for example, has come into widespread use on hole injection layers or hole transport layers.

### SUMMARY OF THE INVENTION

However, in theses prior arts, the driving voltages of the device were not adequately low, though their characteristics had been improved. The reason for this is that the carrier mobility of the hole transport material and the barrier of carrier injection at an interface, which is inherent to the organic EL device, were not improved adequately.

In order to realize the reduction in the driving voltage of an organic EL device, it is necessary to mitigate resistance generated during a hole and an electron are injected from each of injection electrodes and moved to an emission layer. A main source of generating resistance includes bulk resistance and the barrier of carrier injection.

The bulk resistance occurs as a carrier moves in each layer, and it is determined by the component of the layer. For example, a conjugated molecule facilitates carrier transfer by delocalizing π electrons, but nonconjugated molecule reverse the action.

The bulk resistance is represented as values of specific resistance, and the specific resistance may be reduced by enhancing an electrical conductivity which is the reciprocal of the specific resistance. The electrical conductivity is represented as the product of the carrier concentration, the charge and the mobility, and a material having higher mobility exhibits a higher electrical conductivity and can reduce the specific resistance. That is, it is essential to develop a highly electrically conductive or highly mobile material in order to reduce the bulk resistance.

The carrier injection barrier exists at the interface between two adjacent and different layers. Two layers have different energy levels because of various factors such as a component and a production method of a layer. When the carrier is a hole, it is injected into the highest occupied molecular orbital (hereinafter referred to as a HOMO) of the organic material, and the electron is injected into the lowest unoccupied molecular orbital (hereinafter referred to as a LUMO), but the magnitude of a gap between one HOMO level at the interface between two adjacent layers and another HOMO level or the magnitude of a gap between LUMO levels becomes a carrier injection barrier and influences carrier injection efficiency.

Further, the carrier injection barrier tends to occur between two different kinds of materials. For example, the carrier injection barrier occurs in most cases at the interface between an organic material and an inorganic material and the nonexistence of the carrier injection barrier is rather rare. Even among the same organic materials, the carrier injection barrier tends to occur between two layers using organic materials having different basic structures respectively.

In order to reduce the driving voltage of an organic electroluminescence device, it is thought that it is important to reduce the bulk resistance in each layer of a hole injection layer, a hole transport layer and an emission layer and the carrier injection barrier between the respective layers since a material constitution of the respective layers largely has an effect.

Further, in the case of copper phthalocyanine (CuPc) hitherto used, there was a problem that this compound absorbs emission component from the organic electroluminescence device and reduces emission efficiency apparently because of its coloring when it is used in the hole injection layer or the hole transport layer. In order to avoid such a problem, it is necessary to develop a material having high light transmittance in a visible light region.

Against the backdrop of the above state of the art, it is an object of the present invention to provide a hole transport material, having an excellent hole transporting property, for organic electroluminescence devices and an organic electroluminescence device using the same.

The hole transport material for organic electroluminescence devices of the present invention is characterized in that the hole transport material is a copolymer having a first unit consisting of a heterocyclic compound containing a sulfur atom and a second unit consisting of a secondary or tertiary amine compound.

The hole transport material for organic electroluminescence devices of the present invention has the first unit and the second unit. Since each of the first unit and the second unit has an excellent hole transporting property and the hole transport material of the present invention has both of these units as a copolymer of these units, the hole transport material of the present invention becomes a copolymer exhibiting a more excellent hole transporting property by a synergistic effect of having these two units. Accordingly, by using the hole transport material of the present invention for the organic EL device, the hole mobility or the electrical conductivity of the organic EL device can be significantly improved, that is, the bulk resistance can be decreased and the driving voltage can be reduced.

Further, in the present invention, it is preferred that a unit having the same kind of chemical structure as the first unit and the second unit is included in an organic layer adjacent to an organic layer in which the hole transport material of the present invention is used. Two HOMO levels or LUMO levels are often close to each other between organic materials having the same kind of chemical structure, and between organic materials having the same kind of chemical structure or the same level of dipole moment, an adhesion property in laminating organic materials is enhanced and it becomes easy to reduce the carrier injection barrier.

Further, in the hole transport material of the present invention, it is possible to provide a material having high light transmittance in a visible light region by controlling a formulation ratio of the first unit and the second unit. In a conventional polythiophene-based material consisting of only single unit, the hole transport material has high mobility, but is intensely colored in a visible light region, and therefore there was a problem in takeout of emission components. On the other hand, in the hole transport material of the present invention, in which the first unit and the second unit are mixed, it is possible to provide a material having very low coloring in a visible light region.

The heterocyclic compound of the first unit in the copolymer of the present invention is preferably thiophene or a thiophene derivative having a substituent.

Example of the thiophene derivatives include a thiophene derivative expressed by the following formula (1): 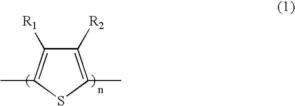
wherein each of R₁ and R₂ is independently any one of the group consisting of hydrogen, and an alkyl group, an alkoxy group and an alkylthio group, having 1 to 20 carbon atoms, and an aryl group and aryloxy group, having 6 to 18 carbon atoms, and a heterocyclic compound group having 4 to 14 carbon atoms,
a thiophene derivative containing cyclic ether expressed by the following formula (2): 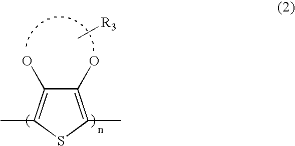
wherein R₃ is any one of the group consisting of hydrogen, and an alkyl group, an alkoxy group and an alkylthio group, having 1 to 20 carbon atoms, and an aryl group and aryloxy group, having 6 to 18 carbon atoms, and a heterocyclic compound group having 4 to 14 carbon atoms,
a thiophene derivative expressed by the following formula (3): 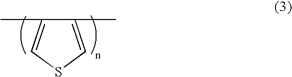
a thiophene derivative expressed by the following formula (4):

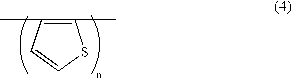

Examples of the secondary or tertiary amine compound of the second unit in the copolymer of the present invention include a diarylamine compound, a triarylamine compound, and a diarylamine derivative and a triarylamine derivative, formed by attaching a substituent to these amine compounds, and a diamine derivative having two nitrogen atoms.

Specific examples of the above secondary or tertiary amine compound include a diamine derivative having two nitrogen atoms expressed by the following formula (5): 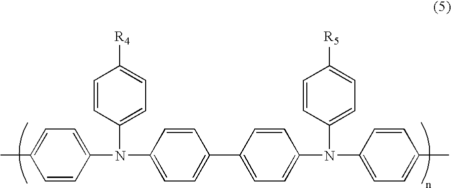
wherein each of R₄ and R₅ is independently any one of the group consisting of hydrogen, and an alkyl group, an alkoxy group and an alkylthio group, having 1 to 20 carbon atoms, and an aryl group and aryloxy group, having 6 to 18 carbon atoms, and a heterocyclic compound group having 4 to 14 carbon atoms,
a triphenylamine derivative expressed by the following formula (6): 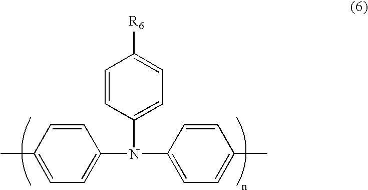
wherein R₆ is any one of the group consisting of hydrogen, and an alkyl group, an alkoxy group and an alkylthio group, having 1 to 20 carbon atoms, and an aryl group and aryloxy group, having 6 to 18 carbon atoms, and a heterocyclic compound group having 4 to 14 carbon atoms,
a carbazole derivative expressed by the following formula (7): 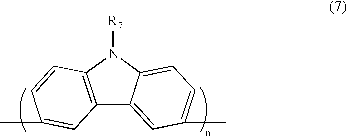
wherein R₇ is any one of the group consisting of hydrogen, and an alkyl group, an alkoxy group and an alkylthio group, having 1 to 20 carbon atoms, and an aryl group and aryloxy group, having 6 to 18 carbon atoms, and a heterocyclic compound group having 4 to 14 carbon atoms,
a naphthylamine derivative expressed by the following formula (8): 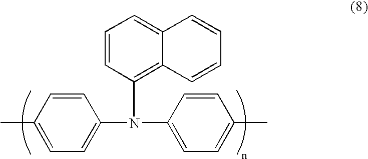
an aniline compound expressed by the following formula (9):

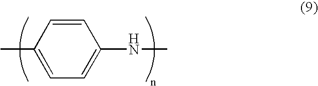

It is preferred that the copolymer of the present invention further includes a third unit having a conjugated structure. As such a third unit, a substance, including a structure of fluorene or a fluorene derivative or a structure of phenylene or a phenylene derivative, is preferred.

Specific examples of the above third unit include a fluorene derivative expressed by the following formula (10): 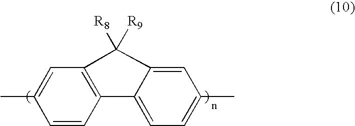
wherein each of R₈ and R₉ is independently any one of the group consisting of hydrogen, and an alkyl group, an alkoxy group and an alkylthio group, having 1 to 20 carbon atoms, and an aryl group and aryloxy group, having 6 to 18 carbon atoms, and a heterocyclic compound group having 4 to 14 carbon atoms,
a fluorene derivative expressed by the following formula (11): 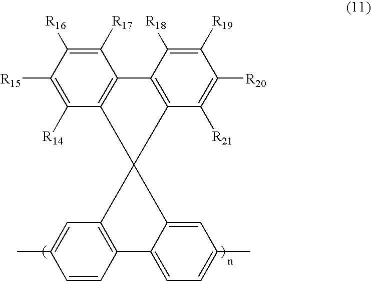
wherein each of R₁₄ to R₂₁ is independently any one of the group consisting of hydrogen, and an alkyl group, an alkoxy group and an alkylthio group, having 1 to 20 carbon atoms, and an aryl group and aryloxy group, having 6 to 18 carbon atoms, and a heterocyclic compound group having 4 to 14 carbon atoms,
a phenylene derivative expressed by the following formula (12): 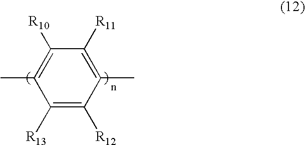
wherein each of R₁₀ to R₁₃ is independently any one of the group consisting of hydrogen, and an alkyl group, an alkoxy group and an alkylthio group, having 1 to 20 carbon atoms, and an aryl group and aryloxy group, having 6 to 18 carbon atoms, and a heterocyclic compound group having 4 to 14 carbon atoms, and
a phenylene derivative expressed by the following formula (13): 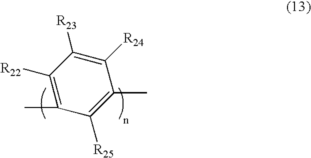
wherein each of R₂₂ to R₂₅ is independently any one of the group consisting of hydrogen, and an alkyl group, an alkoxy group and an alkylthio group, having 1 to 20 carbon atoms, and an aryl group and aryloxy group, having 6 to 18 carbon atoms, and a heterocyclic compound group having 4 to 14 carbon atoms.

An organic EL device of the present invention is characterized in that the organic EL device include an anode, a cathode, an emission layer located between the anode and the cathode and a hole transport layer located between the anode and the emission layer, and the hole transport layer includes the above-mentioned hole transport material of the present invention.

In the organic EL device of the present invention, the hole transport layer includes the hole transport material of the present invention, and thereby, the hole mobility in the organic EL device can be improved and a driving voltage can be reduced.

In the organic EL device of the present invention, it is preferred to provide a hole injection layer between the anode and the hole transport layer. The driving voltage can be further reduced by providing the hole injection layer.

Further, in the organic EL device of the present invention, it is preferred that in adjacent two layers of the hole injection layer, the hole transport layer and the emission layer, a structure which is identical to or similar to a unit structure contained in one layer of the adjacent layers is included in the other layer. For example, when the copolymer of the present invention is contained in the hole transport layer, it is preferred that a structure which is identical to or similar to the first unit or the second unit in the copolymer is contained in the hole injection layer or the emission layer. Thereby, an interface barrier in hole transfer can be mitigated and the driving voltage can be further reduced.

For example, when the first unit of the copolymer of the present invention has a structure of thiophene or a thiophene derivative, the hole injection layer preferably contains a polythiophene-based compound.

Further, when the hole transport layer is composed of a first hole transport layer located on the anode side and a second hole transport layer located on the cathode side, it is preferred that the hole transport material of the present invention is contained in the first hole transport layer and a phenylamine derivative is contained in the second hole transport layer. In this case, it is preferred that the second unit of the copolymer included in the first hole transport layer contains a structure of the phenylamine derivative.

The hole transport material for organic EL devices of the present invention consists of a copolymer having a first unit consisting of a heterocyclic compound containing a sulfur atom and a second unit consisting of a secondary or tertiary amine compound. Since these units take on a structure having an excellent hole transporting property and the copolymer of the present invention has both of such the units, the hole transport material for organic EL devices of the present invention exhibits a more excellent hole transporting property by a synergistic effect of these units. Accordingly, by using the hole transport material of the present invention for the organic EL devices, the hole mobility can be improved and the driving voltage of the organic EL device can be reduced.

### BRIEF DESCRIPTION OF THE DRAWINGS

FIG. 1 is a schematic sectional view showing an organic EL device of an embodiment according to the present invention.

FIG. 2 is a schematic sectional view showing an organic EL device of another embodiment according to the present invention.

FIG. 3 is a schematic sectional view showing an organic EL device of further embodiment according to the present invention.

### DESCRIPTION OF PREFERRED EMBODIMENTS

Hereinafter, the present invention will be described more specifically by way of examples, but the present invention is not limited to the following examples.

FIG. 1 is a schematic sectional view showing an organic EL device of an embodiment according to the present invention.

In an organic EL device shown in FIG. 1, an anode 2 is provided on a substrate 1, and a hole injection layer 3, a hole transport layer 4, an emission layer 5, an electron transport layer 6, and an electron injection layer 7 are provided on the anode 2 in this order. An anode 8 is provided on the electron injection layer 7.

As the substrate 1, for example, transparent substrates consisting of glass or plastic are employed. As the anode 2, for example, transparent conductive films of indium tin oxide (ITO) or the like are employed.

As the hole injection layer 3, for example, polythiophene compounds are preferably employed. The hole injection layer 3 can be formed by using a mixture (PEDOT & PSS) of polyethylenedioxythiophene expressed by the following formula and poly(para-styrene sufonate) and applying a solution of this mixture.

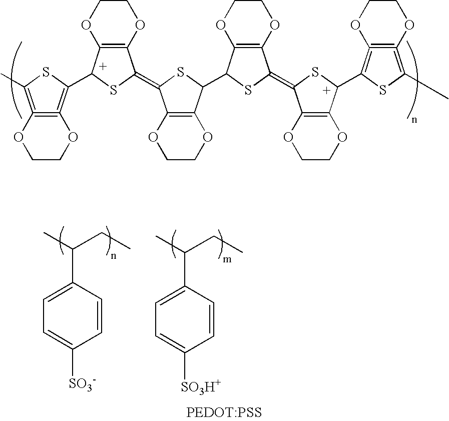

The hole transport layer 4 can be formed from a copolymer of the present invention.

Specific examples of copolymers of the present invention include following copolymers:

poly[(9,9-dioctylfluorene-2,7-diyl)-co-(N,N′-bis(4-tert-butylphenyl)-N,N′-diphenylbenzidine-4′,4″-diyl)-co-(thiophene-2,5-diyl)] (hereinafter, referred to as PF8-tBuTPD-Th) expressed by the following formula:

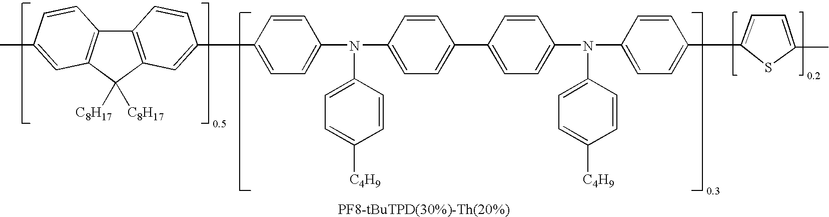

poly[(2,3-dioctyloxybenzene-1,4-diyl)-co-(N,N′-bis(4-tert-butylphenyl)-N,N′-diphenylbenzidine-4′,4″-diyl)-co-(thiophene-2,5-diyl)] (hereinafter, referred to as PDO-tBuTPD-Th) expressed by the following formula:

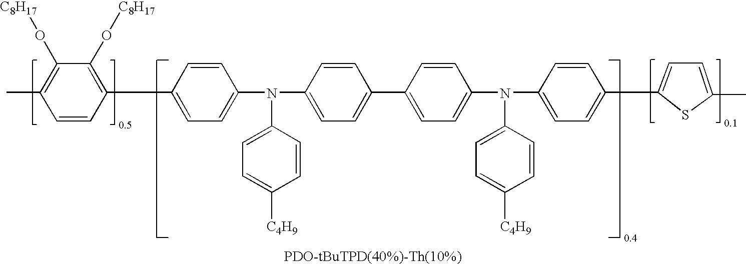

poly[(9,9-dioctylfluorene-2,7-diyl)-co-(N-tolylcarbazol-3,6-diyl)-co-(thiophene-2,5-diyl)] (hereinafter, referred to as PF8-Cz-Th) expressed by the following formula:

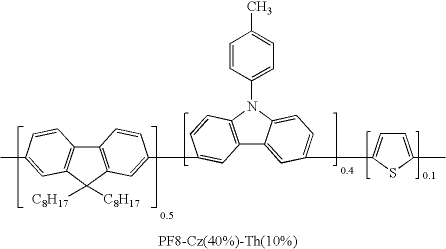

poly[(9,9-dioctylfluorene-2,7-diyl)-co-(N,N′-bis(4-tert-butylphenyl)-N,N′-diphenylbenzidine-4′,4″-diyl)-co-(3,4-ethylenedioxythiophene-2,5-diyl)] (hereinafter, referred to as PF8-tBuTPD-EDOT) expressed by the following formula:

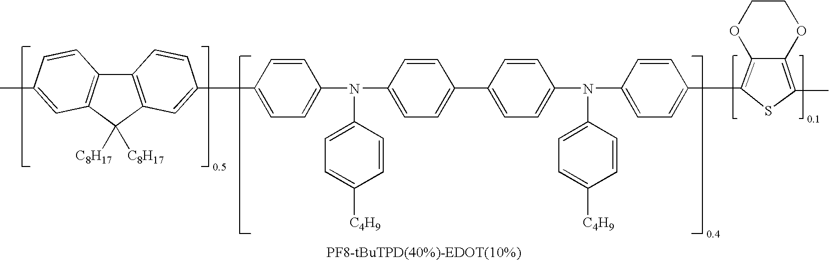

poly[(9,9-dioctylfluorene-2,7-diyl)-co-(triphenylamine-4′,4″-diyl)-co-(3-cyclohexylthiophene-2,5-diyl)] (hereinafter, referred to as PF8-TPA-CyTh) expressed by the following formula:

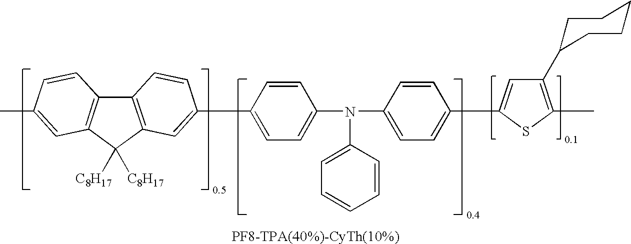

poly[(9,9-dioctylfluorene-2,7-diyl)-co-(N,N′-biphenyl-N-naphtha-1-ylamine-4′,4″-diyl)-co-(thiophene-2,5-diyl)] (hereinafter, referred to as PF8-NPA-Th) expressed by the following formula:

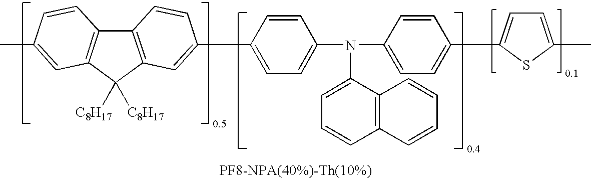

poly[(9,9-dioctylfluorene-2,7-diyl)-co-(N,N′-bis(4-tert-butylphenyl)-N,N′-diphenylbenzidine-4′,4″-diyl)-co-(thiophene-3,4-diyl)] (hereinafter, referred to as PF8-tBuTPD-Thb) expressed by the following formula:

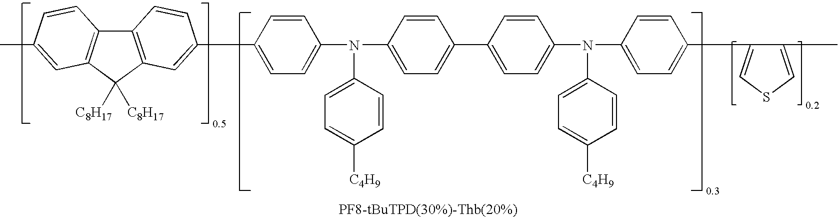

poly[(9,9-dioctylfluorene-2,7-diyl)-co-(N,N′-bis(4-tert-butylphenyl)-N,N′-diphenylbenzidine-4′,4″-diyl)-co-(thiophene-2,3-diyl)] (hereinafter, referred to as PF8-tBuTPD-Thc) expressed by the following formula:

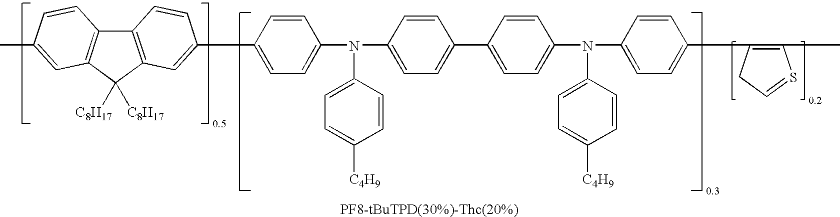

poly[(9-spirofluorofluorene-2,7-diyl)-co-(N,N′-bis(4-tert-butylphenyl)-N,N′-diphenylbenzidine-4′,4″-diyl)-co-(thiophene-2,5-diyl)] (hereinafter, referred to as Spiro-tBuTPD-Th) expressed by the following formula:

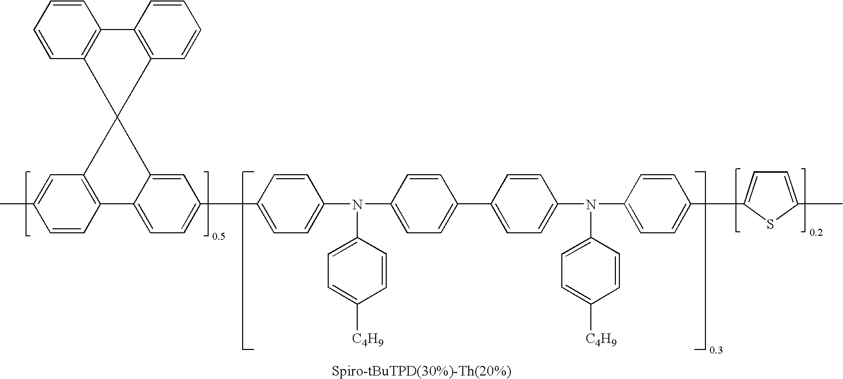

poly[(3-ethylbenz-1,5-diyl)-co-(N,N′-bis(4-tert-butylphenyl)-N,N′-diphenylbenzidine-4′,4″-diyl)-co-(thiophene-2,5-diyl)] (hereinafter, referred to as EB-tBuTPD-Th) expressed by the following formula:

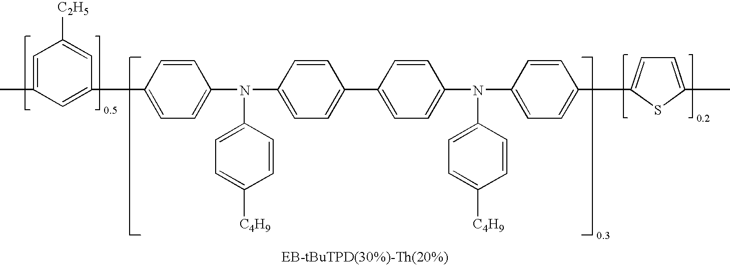

A material of the emission layer 5 may be one which can be used for an emission layer of an organic EL device, and examples of the materials include tris(8-hydroxyquinolinate)aluminum (hereinafter, referred to as Alq3) having the following structure.

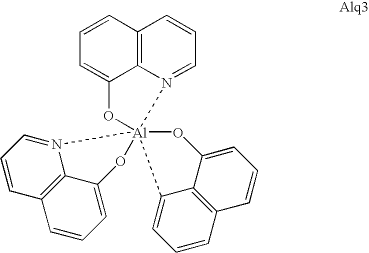

The emission layer 5 may be formed by mixing a dopant material in a host material. As the dopant material, a singlet luminescent material may be used, or a triplet luminescent material may be used. A plurality of dopant materials may be also used. Further, the emission layer 5 may be formed from a polymer material. An emission color can be adjusted by selecting a material composing the emission layer 5. In addition, the emission layer can also be composed of two or more layers.

The electron transport layer 6 is preferably formed from a material having high electron mobility. It can be formed using, for example, the above-mentioned Alq3. Further, it can be formed from 2,9-dimethyl-4,7-diphenyl-1,10-phenanthroline (hereinafter, referred to as BCP) having the following structure.

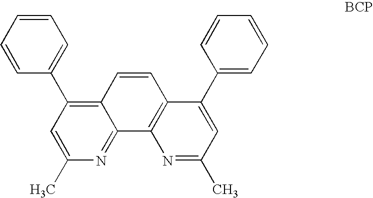

The electron injection layer 7 is preferably formed using a material having high electron injection efficiency. It can be formed from, for example, lithium fluoride (LiF).

The cathode 8 can be formed from, for example, aluminum.

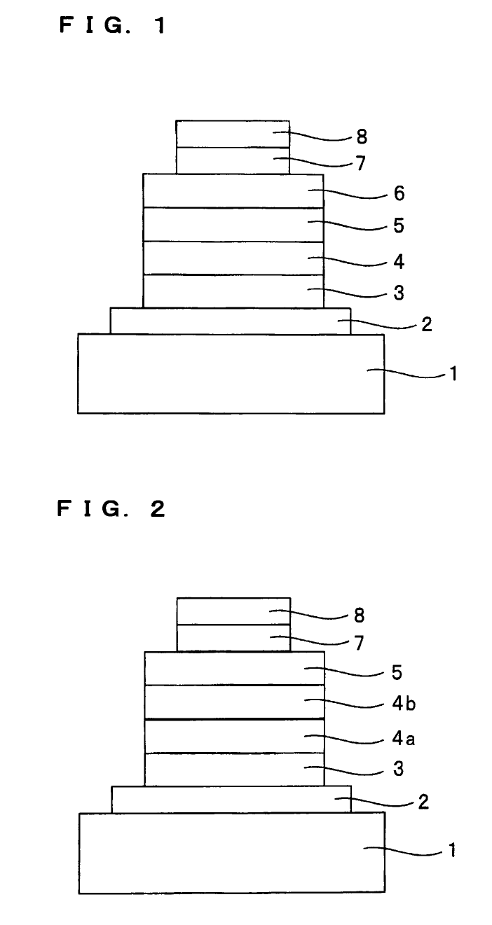

FIG. 2 is a schematic sectional view showing an organic EL device of another embodiment according to the present invention.

An organic EL device shown in FIG. 2 is constructed by providing an anode 2, a hole injection layer 3, a first hole transport layer 4a, a second hole transport layer 4b, an emission layer 5, an electron injection layer 7, and a cathode 8 on a substrate 1 in this order.

In this embodiment, the hole transport layer is composed of the first hole transport layer 4a and the second hole transport layer 4b. The first hole transport layer 4a can be formed by using, for example, the same material as in the hole transport layer 4 of the embodiment shown in FIG. 1. The second hole transport layer 4b can be formed from, for example, a phenylamine derivative. Examples of such phenylamine derivatives include N,N′-di(1-naphthyl)-N,N′-diphenyl-benzidine (hereinafter, referred to as NPB) having the following structure.

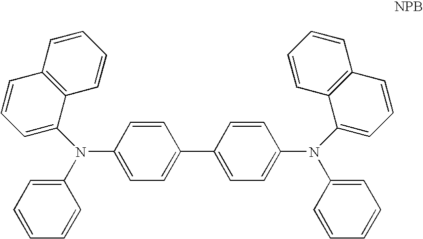

A material composing the second hole transport layer 4b is preferably formed from a compound having a structure which is identical to or similar to a structure of the second unit of the copolymer composing the first hole transport layer 4a.

Another layers can be formed in the same manner as in the embodiment shown in FIG. 1.

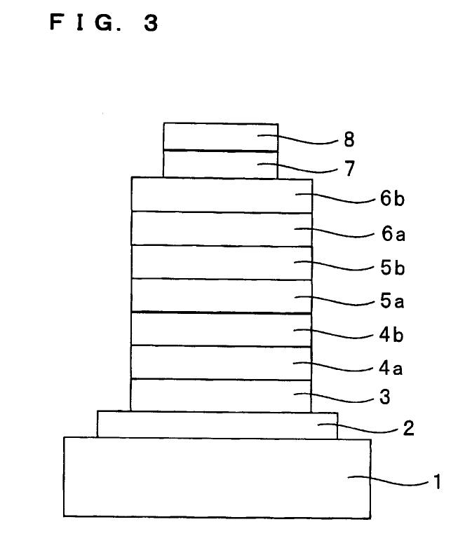

FIG. 3 is a schematic sectional view showing an organic EL device of further embodiment according to the present invention.

An organic EL device shown in FIG. 3 is constructed by providing an anode 2, a hole injection layer 3, a first hole transport layer 4a, a second hole transport layer 4b, a first emission layer 5a, a second emission layer 5b, a first electron transport layer 6a, a second electron transport layer 6b, an electron injection layer 7, and an anode 8 on a substrate 1 in this order.

In this embodiment, the hole transport layer is composed of the first hole transport layer 4a and the second hole transport layer 4b as with the embodiment shown in FIG. 2. These transport layers can be formed in the same manner as in the embodiment shown in FIG. 2.

Further, in this embodiment, the emission layer is composed of the first emission layer 5a and the second emission layer 5b. For example, an organic EL device of white emission can be prepared by forming an orange-red emission layer as the first emission layer 5a and a blue emission layer as the second emission layer 5b. In this case, an organic EL device of full color display capable of displays of three primary colors of light (RGB display) can be prepared by combining a red, a green and a blue filters.

When the orange emission layer is formed as the first emission layer 5a, the orange emission layer can be formed, for example, by employing NPB as a host material, 5,12-bis(4-tert-butylphenyl)-naphthacene (hereinafter, referred to as tBuDPN) having the following structure as a first dopant, and 5,12-bis(4-(6-methylbenzothiazole-2-yl)phenyl)-6,11-diphenylnaphthacene (hereinafter, referred to as DBZR) having the following structure as a second dopant. In this case, the second dopant emits light and the first dopant plays a role of complementing the emission of the second dopant by accelerating energy transfer from the host material to the second dopant. Thereby, the orange emission layer 5a emits orange color having a peak wavelength of longer than 500 nm and shorter than 650 nm.

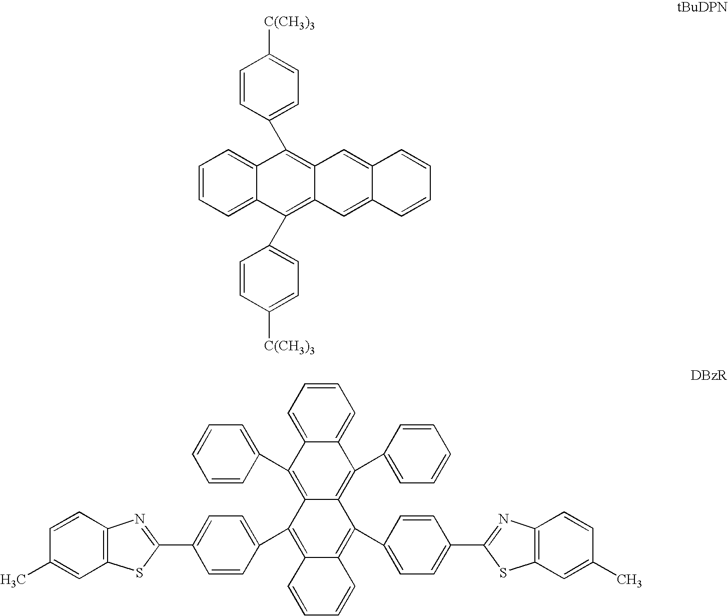

Further, when the blue emission layer is formed as the second emission layer 5b, the blue emission layer may be formed, for example, by employing tert-butyl substituted dinaphthylanthracene (hereinafter, referred to as TBADN) having the following structure as a host material, NPB as a first dopant, and 1,4,7,10-tetra-tert-butylperylene (hereinafter, referred to as TBP) having the following structure as a second dopant. In this case, the second dopant emits light and the first dopant plays a role of complementing the emission of the second dopant by accelerating carrier transport. Thereby, the blue emission layer 5b emits blue color having a peak wavelength of longer than 400 nm and shorter than 500 nm.

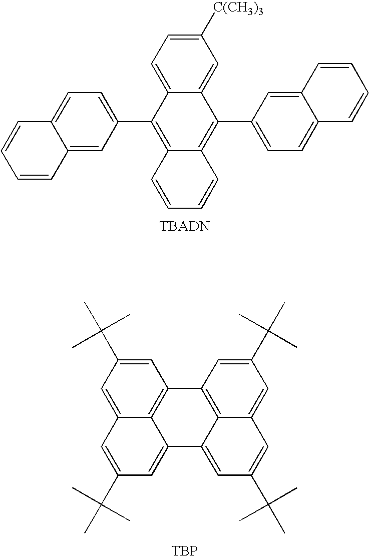

The organic EL device of the present invention is not limited to the organic EL device having the structures of the above embodiments, and for example, an organic EL device of full color display may be formed by combining an organic EL device with an emission layer of green emission, an organic EL device with an emission layer of orange or red emission, and an organic EL device with an emission layer of blue emission.

In the following examples, the organic EL devices of the above embodiments were prepared, and their driving voltages at the time of emission were evaluated.

[Experiment 1]

In Examples 1 to 7 and Comparative Example 1, each organic EL device having a structure shown in FIG. 2 was prepared in the following manner.

### EXAMPLE 1

A copolymer PF8-tBuTPD-Th according to the present invention was synthesized by following the procedure described below.
<Synthesis of PF8-tBuTPD-Th>

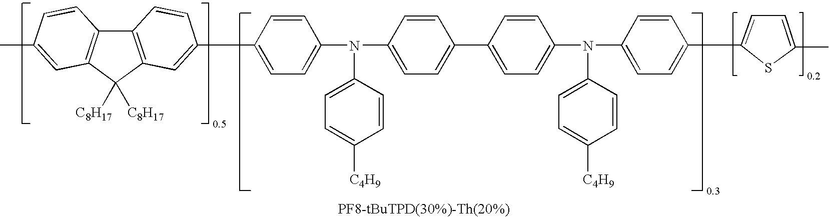

A reaction apparatus equipped with a stirrer was dried well and connected to a nitrogen line/a vacuum line. Into this reactor were charged 48.4 mg (0.2 mmol) of 2,5-dibromothiophene, 227.4 mg (0.3 mmol) of N,N′-bis(4-bromophenyl)-N,N′-bis(4-tert-butylphenyl)-benzidine, 321 mg (0.5 mmol) of 9,9-dioctylfluorene-2,7-bis(4,4,5,5-tetramethyl-1,3,2-dioxaborolan), a catalyst for Suzuki coupling reaction, 5 ml of toluene and 8 ml of a basic aqueous solution. After plugging an opening of the reactor with a rubber stopper, by repeating short-time evacuation and N₂ purge three times, air in the reactor was replaced with nitrogen gas and a solvent was degassed. Then, the reactor was heated to 90° C. and a reaction was continued for about 3 hours in an atmosphere of nitrogen while keeping the reactor at 90° C. Then, 61 mg (0.5 mmol) of phenylboronic acid was added to a reaction solution, and further the reaction was continued at 90° C. for 2 hours in an atmosphere of nitrogen. Then, 0.12 ml (1.1 mmol) of bromobenzene was added to the reaction solution, and further the reaction was continued at 90° C. for 2 hours in an atmosphere of nitrogen. After the completion of the reaction, the reaction solution was cooled to room temperature and added dropwise to 300 ml of methanol to deposit a polymer product. The polymer product was washed with methanol three times and then dried in a vacuum. After this, the polymer product was dissolved in about 10 ml of toluene, and the resulting solution was pass through a short column employing silica gel using toluene as an extractant to remove impurities. The solution exiting the column was concentrated with a rotary evaporator, and then the polymer solution was added dropwise to 300 ml of methanol while stirring the methanol to re-deposit a polymer product. The polymer product was washed with methanol three times and then dried in a vacuum to obtain a final product. The final product was ashen powder polymer. A synthetic yield was about 82%. With respect to the results of molecular weight measurement by GPC, a number-average molecular weight Mn was 32000 and a weight-average molecular weight Mw was 84000 on the polystyrene equivalent basis, respectively, and therefore Mw/Mn was 2.63.

<Preparation of an Organic EL Device>

A substrate 1 with an anode 2 composed of an ITO was used. First, a layer of a mixture (PEDOT & PSS) of polyethylenedioxythiophene and poly(para-styrene sufonate) was formed on the anode 2 so as to have a film thickness of 45 nm by a spin coating method, and a hole injection layer 3 was formed by baking this layer at 200° C. for 15 minutes in the atmosphere.

A first hole transport layer 4a was formed by forming a layer of PF8-tBuTPD-Th on the hole injection layer 3 so as to have a film thickness of 30 nm by a spin coating method and baking this layer at 150° C. for 15 minutes in an atmosphere of nitrogen. In this coating, PF8-tBuTPD-Th was used as a xylene solution.

Subsequently, an emission layer 5 consisting of Alq3 having a film thickness of 60 nm, an electron injection layer 7 consisting of LiF having a film thickness of 1 nm, and a cathode 8 consisting of Al having a film thickness of 200 nm were formed by a vacuum evaporation method on the first hole transport layer 4a.

In addition, in this example, the second hole transport layer 4b was not provided on the first hole transport layer 4a, but the emission layer 5 was provided directly on the first hole transport layer 4a.

### EXAMPLE 2

An organic EL device was prepared by following the same procedure as in Example 1 except for providing a second hole transport layer 4b consisting of NPB having a film thickness of 30 nm on a first hole transport layer 4a and providing an emission layer 5 on the second hole transport layer 4b.

### EXAMPLE 3

A copolymer PDO-tBuTPD-Th according to the present invention was synthesized by following the procedure described below.
<Synthesis of PDO-tBuTPD-Th>

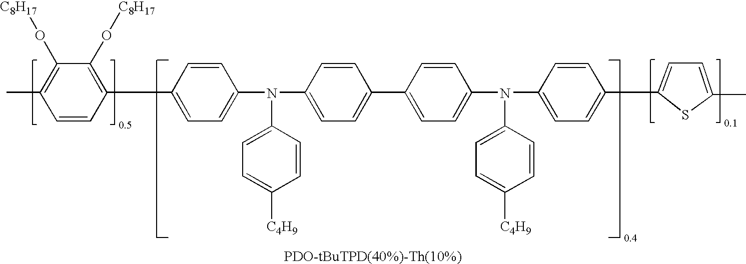

A reaction apparatus equipped with a stirrer was dried well and connected to a nitrogen line/a vacuum line. Into this reactor were charged 24.2 mg (0.1 mmol) of 2,5-dibromothiophene, 303.0 mg (0.4 mmol) of N,N′-bis(4-bromophenyl)-N,N′-bis(4-tert-butylphenyl)-benzidine, 293.0 mg (0.5 mmol) of 2,3-dioctyloxylbenzene-1,4-bis(4,4,5,5-tetramethyl-1,3,2-dioxaborolan), a catalyst for Suzuki coupling reaction, 5 ml of toluene and 8 ml of a basic aqueous solution. After plugging an opening of the reactor with a rubber stopper, by repeating short-time evacuation and N₂ purge three times, air in the reactor was replaced with nitrogen gas and a solvent was degassed. Then, the reactor was heated to 90° C. and a reaction was continued for about 3 hours in an atmosphere of nitrogen while keeping the reactor at 90° C. Then, 61 mg (0.5 mmol) of phenylboronic acid was added to a reaction solution, and further the reaction was continued at 90° C. for 2 hours in an atmosphere of nitrogen. Then, 0.12 ml (1.1 mmol) of bromobenzene was added to the reaction solution, and further the reaction was continued at 90° C. for 2 hours in an atmosphere of nitrogen. After the completion of the reaction, the reaction solution was cooled to room temperature and added dropwise to 300 ml of methanol to deposit a polymer product. The polymer product was washed with methanol three times and then dried in a vacuum. After this, the polymer product was dissolved in about 10 ml of toluene, and the resulting solution was pass through a short column employing silica gel using toluene as an extractant to remove impurities. The solution exiting the column was concentrated with a rotary evaporator, and then the polymer solution was added dropwise to 300 ml of methanol while stirring the methanol to re-deposit a polymer product. The polymer product was washed with methanol three times and then dried in a vacuum to obtain a final product. The final product was yellow-green powder polymer. A synthetic yield was about 86%. With respect to the results of molecular weight measurement by GPC, a number-average molecular weight Mn was 11000 and a weight-average molecular weight Mw was 32000 on the polystyrene equivalent basis, respectively, and therefore Mw/Mn was 2.91.

<Preparation of an Organic EL Device>

An organic EL device was prepared by following the same procedure as in Example 2 except for forming a first hole transport layer 4a using the above copolymer PDO-tBuTPD-Th. Incidentally, the first hole transport layer 4a was formed by a spin coating method as with Example 1.

### EXAMPLE 4

A copolymer PF8-Cz-Th according to the present invention was synthesized by following the procedure described below.
<Synthesis of PF8-Cz-Th>

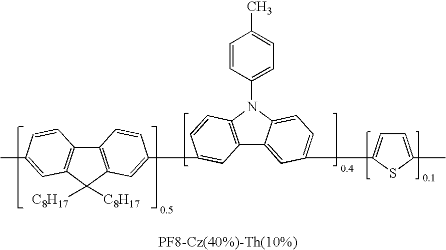

A reaction apparatus equipped with a stirrer was dried well and connected to a nitrogen line/a vacuum line. Into this reactor were charged 24.2 mg (0.1 mmol) of 2,5-dibromothiophene, 166.0 mg (0.4 mmol) of 3,6-dibromo-N-tolylcarbazol, 321 mg (0.5 mmol) of 9,9-dioctylfluorene-2,7-bis(4,4,5,5-tetramethyl-1,3,2-dioxaborolan), a catalyst for Suzuki coupling reaction, 5 ml of toluene and 8 ml of a basic aqueous solution. After plugging an opening of the reactor with a rubber stopper, by repeating short-time evacuation and N₂ purge three times, air in the reactor was replaced with nitrogen gas and a solvent was degassed. Then, the reactor was heated to 90° C. and a reaction was continued for about 3 hours in an atmosphere of nitrogen while keeping the reactor at 90° C. Then, 61 mg (0.5 mmol) of phenylboronic acid was added to a reaction solution, and further the reaction was continued at 90° C. for 2 hours in an atmosphere of nitrogen. Then, 0.12 ml (1.1 mmol) of bromobenzene was added to the reaction solution, and further the reaction was continued at 90° C. for 2 hours in an atmosphere of nitrogen. After the completion of the reaction, the reaction solution was cooled to room temperature and added dropwise to 300 ml of methanol to deposit a polymer product. The polymer product was washed with methanol three times and then dried in a vacuum. After this, the polymer product was dissolved in about 10 ml of toluene, and the resulting solution was pass through a short column employing silica gel using toluene as an extractant to remove impurities. The solution exiting the column was concentrated with a rotary evaporator, and then the polymer solution was added dropwise to 300 ml of methanol while stirring the methanol to re-deposit a polymer product. The polymer product was washed with methanol three times and then dried in a vacuum to obtain a final product. The final product was yellow powder polymer. A synthetic yield was about 88%. With respect to the results of molecular weight measurement by GPC, a number-average molecular weight Mn was 25000 and a weight-average molecular weight Mw was 73000 on the polystyrene equivalent basis, respectively, and therefore Mw/Mn was 2.92.

<Preparation of an Organic EL Device>

An organic EL device was prepared by following the same procedure as in Example 2 except for forming a first hole transport layer 4a by a spin coating method similar to Example 1 using the copolymer PF8-Cz-Th.

### EXAMPLE 5

A copolymer PF8-tBuTPD-EDOT according to the present invention was synthesized by following the procedure described below.
<Synthesis of PF8-tBuTPD-EDOT>

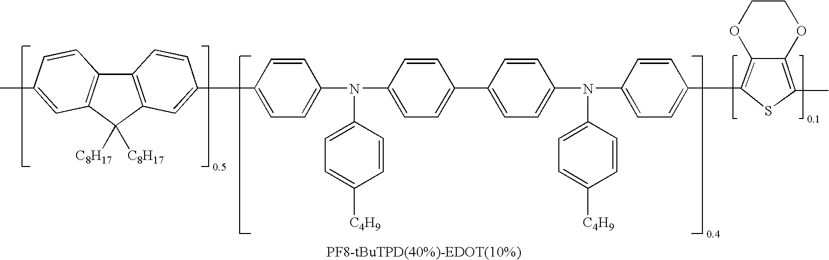

A reaction apparatus equipped with a stirrer was dried well and connected to a nitrogen line/a vacuum line. Into this reactor were charged 30.0 mg (0.1 mmol) of 2,5-dibromo-3,4-ethylenedioxythiophene, 303.2 mg (0.4 mmol) of N,N′-bis(4-bromophenyl)-N,N′-bis(4-tert-butylphenyl)-benzidine, 321 mg (0.5 mmol) of 9,9-dioctylfluorene-2,7-bis(4,4,5,5-tetramethyl-1,3,2-dioxaborolan), a catalyst for Suzuki coupling reaction, 5 ml of toluene and 8 ml of a basic aqueous solution. After plugging an opening of the reactor with a rubber stopper, by repeating short-time evacuation and N₂ purge three times, air in the reactor was replaced with nitrogen gas and a solvent was degassed. Then, the reactor was heated to 90° C. and a reaction was continued for about 3 hours in an atmosphere of nitrogen while keeping the reactor at 90° C. Then, 61 mg (0.5 mmol) of phenylboronic acid was added to a reaction solution, and further the reaction was continued at 90° C. for 2 hours in an atmosphere of nitrogen. Then, 0.12 ml (1.1 mmol) of bromobenzene was added to the reaction solution, and further the reaction was continued at 90° C. for 2 hours in an atmosphere of nitrogen. After the completion of the reaction, the reaction solution was cooled to room temperature and added dropwise to 300 ml of methanol to deposit a polymer product. The polymer product was washed with methanol three times and then dried in a vacuum. After this, the polymer product was dissolved in about 10 ml of toluene, and the resulting solution was pass through a short column employing silica gel using toluene as an extractant to remove impurities. The solution exiting the column was concentrated with a rotary evaporator, and then the polymer solution was added dropwise to 300 ml of methanol while stirring the methanol to re-deposit a polymer product. The polymer product was washed with methanol three times and then dried in a vacuum to obtain a final product. The final product was yellow powder polymer. A synthetic yield was about 88%. With respect to the results of molecular weight measurement by GPC, a number-average molecular weight Mn was 43000 and a weight-average molecular weight Mw was 102000 on the polystyrene equivalent basis, respectively, and therefore Mw/Mn was 2.37.

<Preparation of an Organic EL Device>

An organic EL device was prepared by following the same procedure as in Example 2 except for forming a first hole transport layer 4a by a spin coating method similar to Example 1 using the copolymer PF8-tBuTPD-EDOT.

### EXAMPLE 6

A copolymer PF8-TPA-CyTh according to the present invention was synthesized by following the procedure described below.
<Synthesis of PF8-TPA-CyTh>

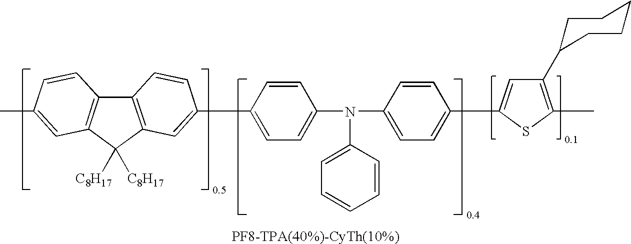

A reaction apparatus equipped with a stirrer was dried well and connected to a nitrogen line/a vacuum line. Into this reactor were charged 32.4 mg (0.1 mmol) of 2,5-dibromo-3-cyclohexylthiophene, 161.2 mg (0.4 mmol) of 4,4-dibromo-triphenylamine, 321 mg (0.5 mmol) of 9,9-dioctylfluorene-2,7-bis(4,4,5,5-tetramethyl-1,3,2-dioxaborolan), a catalyst for Suzuki coupling reaction, 5 ml of toluene and 8 ml of a basic aqueous solution. After plugging an opening of the reactor with a rubber stopper, by repeating short-time evacuation and N₂ purge three times, air in the reactor was replaced with nitrogen gas and a solvent was degassed. Then, the reactor was heated to 90° C. and a reaction was continued for about 3 hours in an atmosphere of nitrogen while keeping the reactor at 90° C. Then, 61 mg (0.5 mmol) of phenylboronic acid was added to a reaction solution, and further the reaction was continued at 90° C. for 2 hours in an atmosphere of nitrogen. Then, 0.12 ml (1.1 mmol) of bromobenzene was added to the reaction solution, and further the reaction was continued at 90° C. for 2 hours in an atmosphere of nitrogen. After the completion of the reaction, the reaction solution was cooled to room temperature and added dropwise to 300 ml of methanol to deposit a polymer product. The polymer product was washed with methanol three times and then dried in a vacuum. After this, the polymer product was dissolved in about 10 ml of toluene, and the resulting solution was pass through a short column employing silica gel using toluene as an extractant to remove impurities. The solution exiting the column was concentrated with a rotary evaporator, and then the polymer solution was added dropwise to 300 ml of methanol while stirring the methanol to re-deposit a polymer product. The polymer product was washed with methanol three times and then dried in a vacuum to obtain a final product. The final product was green powder polymer. A synthetic yield was about 87%. With respect to the results of molecular weight measurement by GPC, a number-average molecular weight Mn was 21000 and a weight-average molecular weight Mw was 65000 on the polystyrene equivalent basis, respectively, and therefore Mw/Mn was 3.10.

<Preparation of an Organic EL Device>

An organic EL device was prepared by following the same procedure as in Example 2 except for forming a first hole transport layer 4a by a spin coating method similar to Example 1 using the copolymer PF8-TPA-CyTh.

### EXAMPLE 7

A copolymer PF8-NPA-Th according to the present invention was synthesized by following the procedure described below.
<Synthesis of PF8-NPA-Th>

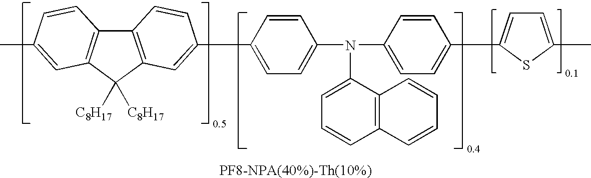

A reaction apparatus equipped with a stirrer was dried well and connected to a nitrogen line/a vacuum line. Into this reactor were charged 24.2 mg (0.1 mmol) of 2,5-dibromothiophene, 181.2 mg (0.4 mmol) of 4,4′-dibromo-N,N′-biphenyl-N-naphtha-1-yl-amine, 321 mg (0.5 mmol) of 9,9-dioctylfluorene-2,7-bis(4,4,5,5-tetramethyl-1,3,2-dioxaborolan), a catalyst for Suzuki coupling reaction, 5 ml of toluene and 8 ml of a basic aqueous solution. After plugging an opening of the reactor with a rubber stopper, by repeating short-time evacuation and N₂ purge three times, air in the reactor was replaced with nitrogen gas and a solvent was degassed. Then, the reactor was heated to 90° C. and a reaction was continued for about 3 hours in an atmosphere of nitrogen while keeping the reactor at 90° C. Then, 61 mg (0.5 mmol) of phenylboronic acid was added to a reaction solution, and further the reaction was continued at 90° C. for 2 hours in an atmosphere of nitrogen. Then, 0.12 ml (1.1 mmol) of bromobenzene was added to the reaction solution, and further the reaction was continued at 90° C. for 2 hours in an atmosphere of nitrogen. After the completion of the reaction, the reaction solution was cooled to room temperature and added dropwise to 300 ml of methanol to deposit a polymer product. The polymer product was washed with methanol three times and then dried in a vacuum. After this, the polymer product was dissolved in about 10 ml of toluene, and the resulting solution was pass through a short column employing silica gel using toluene as an extractant to remove impurities. The solution exiting the column was concentrated with a rotary evaporator, and then the polymer solution was added dropwise to 300 ml of methanol while stirring the methanol to re-deposit a polymer product. The polymer product was washed with methanol three times and then dried in a vacuum to obtain a final product. The final product was ashen powder polymer. A synthetic yield was about 89%. With respect to the results of molecular weight measurement by GPC, a number-average molecular weight Mn was 54000 and a weight-average molecular weight Mw was 132000 on the polystyrene equivalent basis, respectively, and therefore Mw/Mn was 2.44.

<Preparation of an Organic EL Device>

An organic EL device was prepared by following the same procedure as in Example 1 except for forming a first hole transport layer 4a by a spin coating method similar to Example 1 using copolymer PF8-NPA-Th.

### COMPARATIVE EXAMPLE 1

<Preparation of an Organic EL Device>

An organic EL device was prepared by following the same procedure as in Example 2 except for forming a first hole transport layer 4a by a spin coating method similar to Example 1 using polyvinylcarbazole (PVK) having the following structure: 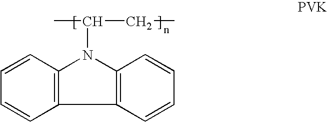
(Evaluation of an Organic EL Device)

The emission characteristics of the organic EL devices of Examples 1 to 7 and Comparative Example 1 were evaluated. The driving voltages in driving the devices at a driving current of 20 mA/cm² are shown in Table 1. The materials of the hole injection layer, the first hole transport layer and the second hole transport layer are shown together in Table 1.

TABLE 1

| | | | Second | Driving |
|---|---|---|---|---|
| | Hole | | Hole | Voltage |
| | Injection | First Hole | Transport | (V) (at 20 |
| | Layer | Transport Layer | Layer | mA/cm²) |
| Example 1 | PEDOT:PSS | PF8-tBuTPD-Th | — | 7.7 |
| Example 2 | PEDOT:PSS | PF8-tBuTPD-Th | NPB | 7.5 |
| Example 3 | PEDOT:PSS | PDO-tBuTPD-Th | NPB | 7.5 |
| Example 4 | PEDOT:PSS | PF8-Cz-Th | NPB | 8 |
| Example 5 | PEDOT:PSS | PF8-tBuTPD-EDOT | NPB | 8.7 |
| Example 6 | PEDOT:PSS | PF8-TPA-CyTh | NPB | 8 |
| Example 7 | PEDOT:PSS | PF8-NPA-Th | NPB | 8 |
| Comparative | PEDOT:PSS | PVK | NPB | 10 |
| Example 1 | | | | |

As shown in Table 1, it is understood that the driving voltages of the organic EL devices of Examples 1 to 7 were lower than that of Comparative Example 1.

It is thought that since the first hole transport layer 4a is formed using the copolymer according to the present invention in the organic EL devices of Examples 1 to 7, the hole mobility in the organic EL device was improved and thereby a low driving voltage was attained.

Further, in Examples 1 to 7, a polythiophene compound is used in the hole injection layer 3, and the copolymer of the present invention having a structure of a thiophene derivative as a first unit is used in the first hole transport layer 4a adjacent to the hole injection layer 3. In addition, in Examples 2 to 7, a NPB, a phenylamine derivative, is used in the second hole transport layer 4b, and the copolymer of the present invention having a structure of a phenylamine derivative as a second unit is used in the first hole transport layer 4a adjacent to the second hole transport layer 4b. Thus, it is thought that thereby, the barrier in hole transfer, existing at the interface between the hole injection layer 3 and the first hole transport layer 4a and the interface between the first hole transport layer 4a and the second hole transport layer 4b, respectively, is mitigated and the driving voltage is reduced.

On the other hand, in Comparative Example 1, it is thought that since a PVK is employed as the first hole transport layer 4a, a relationship between two adjacent layers described above does not exists, and therefore the driving voltage is increased.

[Experiment 2]

Each organic EL device, having a structure shown in FIG. 3, of Examples 8 to 13 and Comparative Example 2 was prepared in the following manner.

### EXAMPLE 8

<Preparation of an Organic EL Device>

A hole injection layer 3 was formed by using a substrate with an anode 2 composed of an ITO, forming a layer of PEDOT & PSS on the anode 2 so as to have a film thickness of 45 nm by a spin coating method and baking this layer at 200° C. for 15 minutes in the atmosphere.

A first hole transport layer 4a was formed by forming a layer of PF8-tBuTPD-Th on the hole injection layer 3 so as to have a film thickness of 30 nm by a spin coating method and baking this layer at 150° C. for 15 minutes in an atmosphere of nitrogen. In this coating, PF8-tBuTPD-Th was used as a xylene solution.

Subsequently, a second hole transport layer 4b consisting of NPB having a film thickness of 30 nm was formed on the first hole transport layer 4a by a vacuum evaporation method. An orange emission layer 5a was formed by adding a first dopant consisting of tBuDPN in an amount of 10% by weight and a second dopant consisting of DBzR in an amount of 3% by weight, respectively, to a host material having a thickness of 30 nm and consisting of NPB.

An blue emission layer 5b was formed by adding a first dopant consisting of NPB in an amount of 20% by weight and a second dopant consisting of TBP in an amount of 1% by weight, respectively, to a host material having a thickness of 60 nm and consisting of TBADN.

Subsequently, a first electron transport layer 6a consisting of Alq3 having a film thickness of 3 nm, a second electron transport layer 6b consisting of BCP having a film thickness of 7 nm, an electron injection layer 7 consisting of LiF having a film thickness of 1 nm, and a cathode 8 consisting of Al having a film thickness of 200 nm were formed by a vacuum evaporation method.

### EXAMPLE 9

An organic EL device was prepared by following the same procedure as in Example 8 except for forming a first hole transport layer 4a by a spin coating method similar to Example 8 using the copolymer PDO-tBuTPD-Th according to the present invention.

### EXAMPLE 10

An organic EL device was prepared by following the same procedure as in Example 8 except for forming a first hole transport layer 4a by a spin coating method similar to Example 8 using the copolymer PF8-Cz-Th according to the present invention.

### EXAMPLE 11

An organic EL device was prepared by following the same procedure as in Example 8 except for forming a first hole transport layer 4a by a spin coating method similar to Example 8 using the copolymer PF8-tBuTPD-EDOT according to the present invention.

### EXAMPLE 12

An organic EL device was prepared by following the same procedure as in Example 8 except for forming a first hole transport layer 4a by a spin coating method similar to Example 8 using the copolymer PF8-TPA-CyTh according to the present invention.

### EXAMPLE 13

An organic EL device was prepared by following the same procedure as in Example 8 except for forming a first hole transport layer 4a by a spin coating method similar to Example 8 using the copolymer PF8-NPA-Th according to the present invention.

### COMPARATIVE EXAMPLE 2

An organic EL device was prepared by following the same procedure as in Example 8 except for forming a first hole transport layer 4a by a spin coating method similar to Example 8 using PVK.

(Evaluation of an Organic EL Device)

The emission characteristics of the organic EL devices of Examples 8 to 13 and Comparative Example 2 were evaluated. The driving voltages in driving the devices at a driving current of 20 mA/cm² are shown in Table 2. The materials of the hole injection layer, the first hole transport layer and the second hole transport layer are shown together in Table 2.

TABLE 2

| | | | Second | Driving |
|---|---|---|---|---|
| | Hole | | Hole | Voltage |
| | Injection | First Hole | Transport | (V) (at 20 |
| | Layer | Transport Layer | Layer | mA/cm²) |
| Example 8 | PEDOT:PSS | PF8-tBuTPD-Th | NPB | 3.5 |
| Example 9 | PEDOT:PSS | PDO-tBuTPD-Th | NPB | 3.6 |
| Example 10 | PEDOT:PSS | PF8-Cz-Th | NPB | 4.2 |
| Example 11 | PEDOT:PSS | PF8-tBuTPD-EDOT | NPB | 4.5 |
| Example 12 | PEDOT:PSS | PF8-TPA-CyTh | NPB | 4.0 |
| Example 13 | PEDOT:PSS | PF8-NPA-Th | NPB | 4.0 |
| Comparative | PEDOT:PSS | PVK | NPB | 5.4 |
| Example 2 | | | | |

As shown in Table 2, it is understood that the driving voltages of the organic EL devices of Examples 8 to 13 were lower than that of Comparative Example 2.

It is thought that since the first hole transport layer 4a is formed using the copolymer according to the present invention in the organic EL devices of Examples 8 to 13, the hole mobility in the organic EL device was improved and thereby a low driving voltage was attained.

Further in Examples 8 to 13, a polythiophene compound is used in the hole injection layer 3, and the copolymer of the present invention having a structure of a thiophene derivative as a first unit is used in the first hole transport layer 4a adjacent to the hole injection layer 3. In addition, a NPB, a phenylamine derivative, is used in the second hole transport layer 4b, and the copolymer of the present invention having a structure of a phenylamine derivative as a second unit is used in the first hole transport layer 4a adjacent to the second hole transport layer 4b. Thus, it is thought that thereby, the barrier in hole transfer, existing at the interface between the hole injection layer 3 and the first hole transport layer 4a and the interface between the first hole transport layer 4a and the second hole transport layer 4b, respectively, is mitigated and the driving voltage is reduced.

On the other hand, in Comparative Example 2, it is thought that since a PVK is employed as the first hole transport layer 4a, a relationship between two adjacent layers described above does not exists, and therefore the driving voltage is increased.

What is claimed is:

1. A hole transport material for organic electroluminescence devices, wherein the hole transport material is a copolymer having a first unit consisting of a heterocyclic compound containing a sulfur atom and a second unit consisting of a secondary or tertiary amine compound.

2. The hole transport material for organic electroluminescence devices according to claim 1, wherein said heterocyclic compound of the first unit is thiophene or a thiophene derivative having a substituent.

3. The hole transport material for organic electroluminescence devices according to claim 1, wherein said secondary or tertiary amine compound of the second unit is a diarylamine compound, a triarylamine compound, or a diarylamine derivative or a triarylamine derivative, formed by attaching a substituent to these amine compounds.

4. The hole transport material for organic electroluminescence devices according to claim 3, wherein an aryl group is a phenyl group or a naphthyl group in said diarylamine compound, said triarylamine compound, or said diarylamine derivative or said triarylamine derivative, formed by attaching a substituent to these amine compounds.

5. The hole transport material for organic electroluminescence devices according to claim 1, wherein said secondary or tertiary amine compound of the second unit is a diamine derivative having two nitrogen atoms.

6. The hole transport material for organic electroluminescence devices according to claim 1, wherein said copolymer further includes a third unit having a conjugated structure.

7. The hole transport material for organic electroluminescence devices according to claim 6, wherein said third unit includes a structure of fluorene or a fluorene derivative.

8. The hole transport material for organic electroluminescence devices according to claim 6, wherein said third unit includes a structure of phenylene or a phenylene derivative.

9. The hole transport material for organic electroluminescence devices according to claim 2, wherein said heterocyclic compound of the first unit is a thiophene derivative expressed by the following formula (1): 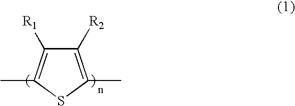
wherein each of R₁ and R₂ is independently any one of the group consisting of hydrogen, and an alkyl group, an alkoxy group and an alkylthio group, having 1 to 20 carbon atoms, and an aryl group and aryloxy group, having 6 to 18 carbon atoms, and a heterocyclic compound group having 4 to 14 carbon atoms.

10. The hole transport material for organic electroluminescence devices according to claim 2, wherein said heterocyclic compound of the first unit is a thiophene derivative containing cyclic ether expressed by the following formula (2): 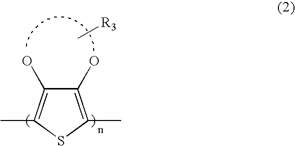
wherein R₃ is any one of the group consisting of hydrogen, and an alkyl group, an alkoxy group and an alkylthio group, having 1 to 20 carbon atoms, and an aryl group and aryloxy group, having 6 to 18 carbon atoms, and a heterocyclic compound group having 4 to 14 carbon atoms.

11. The hole transport material for organic electroluminescence devices according to claim 5, wherein said secondary or tertiary amine compound of the second unit is a diamine derivative having two nitrogen atoms expressed by the following formula (5): 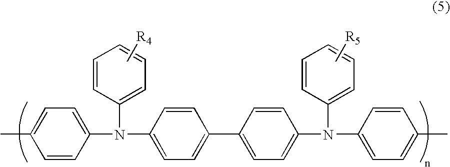
wherein each of R₄ and R₅ is independently any one of the group consisting of hydrogen, and an alkyl group, an alkoxy group and an alkylthio group, having 1 to 20 carbon atoms, and an aryl group and aryloxy group, having 6 to 18 carbon atoms, and a heterocyclic compound group having 4 to 14 carbon atoms.

12. The hole transport material for organic electroluminescence devices according to claim 4, wherein said secondary or tertiary amine compound of the second unit is a triphenylamine derivative expressed by the following formula (6): 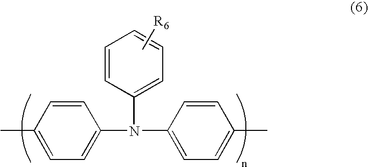
wherein R₆ is any one of the group consisting of hydrogen, and an alkyl group, an alkoxy group and an alkylthio group, having 1 to 20 carbon atoms, and an aryl group and aryloxy group, having 6 to 18 carbon atoms, and a heterocyclic compound group having 4 to 14 carbon atoms.

13. The hole transport material for organic electroluminescence devices according to claim 1, wherein said secondary or tertiary amine compound of the second unit is a carbazole derivative expressed by the following formula (7): 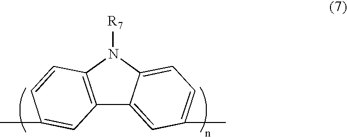
wherein R₇ is any one of the group consisting of hydrogen, and an alkyl group, an alkoxy group and an alkylthio group, having 1 to 20 carbon atoms, and an aryl group and aryloxy group, having 6 to 18 carbon atoms, and a heterocyclic compound group having 4 to 14 carbon atoms.

14. The hole transport material for organic electroluminescence devices according to claim 1, wherein said secondary or tertiary amine compound of the second unit is a naphthylamine derivative expressed by the following formula (8):

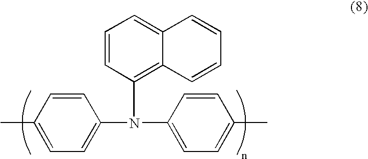

15. The hole transport material for organic electroluminescence devices according to claim 7, wherein said third unit has a structure of a fluorene derivative expressed by the following formula (10): 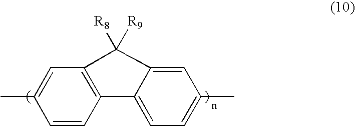
wherein each of R₈ and R₉ is independently any one of the group consisting of hydrogen, and an alkyl group, an alkoxy group and an alkylthio group, having 1 to 20 carbon atoms, and an aryl group and aryloxy group, having 6 to 18 carbon atoms, and a heterocyclic compound group having 4 to 14 carbon atoms.

16. The hole transport material for organic electroluminescence devices according to claim 8, wherein said third unit has a structure of a phenylene derivative expressed by the following formula (12): 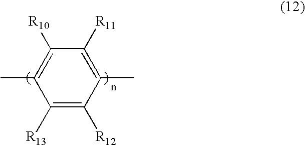
wherein each of R₁₀ to R₁₃ is independently any one of the group consisting of hydrogen, and an alkyl group, an alkoxy group and an alkylthio group, having 1 to 20 carbon atoms, and an aryl group and aryloxy group, having 6 to 18 carbon atoms, and a heterocyclic compound group having 4 to 14 carbon atoms.

17. An organic electroluminescence device including an anode, a cathode, an emission layer located between said anode and said cathode and a hole transport layer located between said anode and said emission layer, wherein said hole transport layer includes the hole transport material according to claim 1.

18. The organic electroluminescence device according to claim 17, wherein a hole injection layer is provided between said anode and said hole transport layer.

19. The organic electroluminescence device according to claim 18, wherein in adjacent two layers of said hole injection layer, said hole transport layer and said emission layer, a structure which is identical to or similar to a unit structure contained in one layer of the adjacent layers is included in the other layer.

20. The organic electroluminescence device according to claim 18, wherein said hole injection layer contains polythiophene compounds.

21. The organic electroluminescence device according to claim 17, wherein said hole transport layer is composed of a first hole transport layer located on said anode side and a second hole transport layer located on said cathode side, said first hole transport layer contains the hole transport material according to claim 1, and said second hole transport layer contains a phenylamine derivative.
